(19) United States
(12) Patent Application Publication
(10) Pub. No.: US 2009/0230408 A1
(43) Pub. Date: Sep. 17, 2009

(54) OPTICAL DEVICE AND METHOD FOR MANUFACTURING THE SAME

(76) Inventors: Hu Meng, Osaka (JP); Hiroto Ohsaki, Kyoto (JP)

Correspondence Address: MCDERMOTT WILL & EMERY LLP, 600 13TH STREET, NW, WASHINGTON, DC, 20005-3096, US

(21) Appl. No.: 12/396,183

(22) Filed: Mar. 2, 2009

(30) Foreign Application Priority Data
Mar. 5, 2008 (JP) 2008-055099
Jan. 20, 2009 (JP) 2009-009868

(51) Int. Cl. H01L 33/00; H01L 21/50

(52) U.S. Cl. 257/81; 438/25; 257/E33.076; 257/E33.056; 257/E21.499

(57) ABSTRACT

An optical device includes a semiconductor substrate including a device region formed thereon, the device region including at least one of a light-receiving region and a light-emitting region; a light-transmissive flattening film covering the device region, and including a first concave portion located in a region on an outer side of the device region; a light-transmissive member formed on the light-transmissive flattening film; and a light-transmissive adhesive layer bonding together the light-transmissive flattening film and the light-transmissive member, and filling the first concave portion.

### CROSS-REFERENCE TO RELATED APPLICATION

This application claims priority from Japanese Patent Application JP2008-055099 filed on Mar. 5, 2008 and Japanese Patent Application JP2009-009868 filed on Jan. 20, 2009, the disclosure of which application is hereby incorporated by reference into this application in its entirety for all purposes.

### BACKGROUND OF THE INVENTION

The present disclosure relates to an optical device including an image sensor such as a CCD (Charge Coupled Device) and a CMOS (Complementary Metal Oxide Semiconductor), a light receiving element such as a photodiode, a phototransistor and a photo IC (Integrated Circuit), and a light emitting element such as an LED (Light Emitting Diode) and a semiconductor laser, and a method for manufacturing the same.

In recent years, direct attachment structures have been proposed in the art, instead of conventional hollow package structures, for package structures of optical devices such as solid-state imaging devices (see, for example, Japanese Published Patent Application No. 1-103-151666). FIG. 13 is a cross-sectional view showing a solid-state imaging device having a conventional direct attachment structure. As shown in FIG. 13, in a solid-state imaging device having a conventional direct attachment structure, a cap glass 201 is formed directly on an image sensor section 203 formed on a chip 202. The direct attachment structure refers to a structure in which a light-transmissive board is directly attached to a light-receiving/light-emitting region provided on a semiconductor substrate by a light-transmissive adhesive. An advantage of the direct attachment structure is that the sensitivity of the optical device can be increased by making uniform the refractive indices of the light-transmissive board, the light-transmissive adhesive, and the light-transmissive film formed on the semiconductor substrate. Moreover, by employing the direct attachment structure, it is possible to more easily reduce the size and the thickness of the package, and to prevent dust from being mixed in the light-receiving/light-emitting region during the manufacturing process, for example.

A solid-state imaging device having a direct attachment structure shown in FIG. 14 has also been proposed in the art. FIG. 14 is a perspective view showing an example of a solid-state imaging device having a conventional direct attachment structure. As shown in FIG. 14, the conventional solid-state imaging device includes a solid-state imaging element 111 including a semiconductor substrate 104 with a light-receiving/light-emitting section 101 and electrode sections 107 formed thereon, and a light-transmissive board 102 directly attached to the semiconductor substrate 104 by a light-transmissive adhesive 110 so as to cover the light-receiving/light-emitting section 101. The solid-state imaging element 111 is placed on a substrate 108 with leads 109 provided thereon.

A solid-state imaging device having the direct attachment structure shown in FIG. 14 may have a problem as shown in FIGS. 15A and 15B. FIG. 15A is a plan view showing a problem of the conventional solid-state imaging device, and FIG. 15B is a cross-sectional view taken along line XV-XV in FIG. 15A.

As shown in FIGS. 15A and 15B, with the conventional solid-state imaging device, when the light-transmissive board 102 is mounted on the semiconductor substrate 104 by the light-transmissive adhesive 110, the light-transmissive adhesive 110 may flow substantially over the edge of the light-transmissive board 102, as viewed from above, so as to adhere to the electrode sections 107 provided in a peripheral portion of the semiconductor substrate 104.

In view of such a problem, a solid-state imaging device shown in FIGS. 16 and 17, for example, has been proposed in the art (see, for example, Japanese Published Patent Application No. 2007-150266). FIG. 16 is a perspective view showing a configuration of the conventional solid-state imaging device. FIG. 17 is a cross-sectional view showing a configuration of the solid-state imaging device of FIG. 16. As shown in FIGS. 16 and 17, the conventional solid-state imaging device includes a flattening film 103 formed on the semiconductor substrate 104, where the flattening film 103 includes protruding portions 106 extending between the light-receiving/light-emitting section 101 and the electrode sections 107 as viewed from above. With the protruding portions 106, it is possible to prevent the light-transmissive adhesive 110 from flowing into the electrode sections 107.

### SUMMARY OF THE INVENTION

In the conventional solid-state imaging device shown in FIGS. 16 and 17, however, since the height of the protruding portions 106 is only on the order of micrometers, there may occur a problem as shown in FIGS. 18A and 18B. FIG. 18A is a plan view showing a problem of the conventional solid-state imaging device, and FIG. 18B is a cross-sectional view taken along line XVIIIb-XVIIIb in FIG. 18A.

As shown in FIGS. 18A and 18B, even if the protruding portions 106 are formed on the semiconductor substrate 104 in the conventional solid-state imaging device, the light-transmissive adhesive 110 may still flow over the protruding portions 106 into the electrode sections 107. Even if one attempts to further increase the height of the protruding portions 106, for example, in order to block the flow of the light-transmissive adhesive over the protruding portions 106, the height of the protruding portions 106 can be increased only to a height on the order of 10 micrometers, and it is therefore not possible to completely prevent the overflow of the light-transmissive adhesive 110. Moreover, if one attempts to alleviate the problem by increasing the height of the protruding portions 106, it is difficult to reduce the size of the optical device. Furthermore, an increased thickness of the light-transmissive adhesive may result in a decrease in the light-collecting efficiency due to reflection loss.

In the conventional solid-state imaging device, if there is any hollow portion between the semiconductor substrate 104 and the light-transmissive board (glass plate) 102, the refractive index is varied in the hollow portion, thereby causing a problem in transmitting/receiving light. Therefore, it is necessary to apply a larger amount of the light-transmissive adhesive 110 on the light-receiving/light-emitting section 101 so that the light-transmissive adhesive 110 completely covers the light-receiving/light-emitting section 101 and so that no hollow portion is formed. This makes it more likely that the light-transmissive adhesive 110 flows onto the electrode sections 107 as it is flattened out by the light-transmissive board 102. Particularly, when reducing the size of the package including the semiconductor substrate 104, the light-transmissive adhesive 110 is more likely to flow onto the side surface (the outer side) of the semiconductor substrate 104. The solution of this problem has been a pressing need in the art.

With an example optical device and an example method for manufacturing the same disclosed in the present specification, it is possible to realize a direct attachment structure having a reduced size and desirable performance, while suppressing the overflow of the light-transmissive adhesive into the electrode sections.

In order to solve the problems set forth above, an example optical device includes a semiconductor substrate including a device region formed thereon, the device region including at least one of a light-receiving region and a light-emitting region; a light-transmissive flattening film covering the device region, and including a first concave portion located in a region on an outer side of the device region; a light-transmissive member formed on the light-transmissive flattening film; and a light-transmissive adhesive layer bonding together the light-transmissive flattening film and the light-transmissive member, and filling the first concave portion.

With this configuration where the first concave portion is provided in the light-transmissive film, a portion of the light-transmissive adhesive that flows onto a peripheral portion of the light-transmissive member runs into the first concave portion when the light-transmissive member is directly bonded onto the light-transmissive adhesive. Therefore, it is possible to prevent the light-transmissive adhesive from flowing over to unnecessary portions such as an edge portion and a side surface of the semiconductor substrate. With the provision of the first concave portion, a larger amount of the light-transmissive adhesive can be used for bonding the light-transmissive member, whereby the gap between the light-transmissive flattening film and the light-transmissive member can more reliably be filled with the light-transmissive adhesive layer, thus realizing a uniform transmission for incident light.

The optical device may further include an electrode pad provided on a portion of the semiconductor substrate that is located on a same surface as the device region and on an outer side of the device region, wherein the first concave portion is formed between the device region and the electrode pad. Then, it is possible to prevent the light-transmissive adhesive from flowing onto the electrode pad. Therefore, with this configuration, it is possible to realize an optical device of a direct attachment structure having a reduced size, a high sensitivity and desirable performance, while suppressing adhesion of the light-transmissive adhesive layer onto the electrode pad.

An edge of the light-transmissive adhesive layer may be located on the semiconductor substrate on an outer side of the light-transmissive member and on an inner side of the electrode pad.

The optical device may further include a protruding portion provided in a region on the light-transmissive flattening film that is between the first concave portion and the electrode pad, wherein the light-transmissive member is placed on the protruding portion. Then, it is possible to more reliably prevent the light-transmissive adhesive from flowing to the outside of the semiconductor substrate in the process of placing the light-transmissive member. Moreover, with the protruding portion, the placement of the light-transmissive member can be made more stable, thereby suppressing deterioration in the optical characteristics.

A plurality of the electrode pads may be provided in a row or rows; and the first concave portion and the protruding portion may each be formed so as to extend along the row or rows of the electrode pads.

A planar shape of the semiconductor substrate may be rectangular; and the electrode pads may be provided along one or more sides of the semiconductor substrate.

A second concave portion is formed in a portion of the light-transmissive flattening film that is located on an outer side of the device region and along a side of the semiconductor substrate where the electrode pads are absent; and the second concave portion may be filled with the light-transmissive adhesive layer.

The electrode pads may be provided along two opposing sides of the semiconductor substrate.

If the optical device further includes a through electrode running through the semiconductor substrate and located on an outer side of the device region, it is possible to further reduce the planar size.

The first concave portion may be formed on an outer side of the light-transmissive member.

The first concave portion may be formed on an inner side of the light-transmissive member.

The optical device may further include a protruding portion provided on a portion of the light-transmissive flattening film that is located on an outer side of a portion where the first concave portion is provided, wherein the light-transmissive member is placed on the protruding portion.

An inner surface of the first concave portion may be tapered.

An example method for manufacturing an optical device includes the steps of (a) providing a semiconductor substrate including a device region formed thereon, the device region including at least one of a light-receiving region and a light-emitting region, and forming a light-transmissive flattening film covering the device region on the semiconductor substrate; (b) forming a concave portion in a region of the light-transmissive flattening film that is located on an outer side of the device region; and (c) placing a light-transmissive member on the semiconductor substrate and the light-transmissive flattening film so as to cover the device region with a light-transmissive adhesive interposed therebetween, thereby forming a light-transmissive adhesive layer, obtained by curing the light-transmissive adhesive, on the semiconductor substrate and the light-transmissive flattening film filling the concave portion, and bonding the light-transmissive member to the light-transmissive flattening film with the light-transmissive adhesive layer interposed therebetween, after the step (b).

In this method, the concave portion is formed in a region of the light-transmissive flattening film that is located on an outer side of the device region in the step (b). Therefore, even if the light-transmissive adhesive flows onto a peripheral portion of the light-transmissive member when the light-transmissive member is directly bonded onto the light-transmissive flattening film in the step (c), the light-transmissive adhesive can be held in the concave portion. Thus, it is possible to prevent the light-transmissive adhesive from flowing over to the edge portion of the semiconductor substrate. As a result, in a case where electrode pads are provided along edge portions of the semiconductor substrate, for example, a defective connection is suppressed in the process of wire-bonding the electrode pads to leads, or the like, thereby allowing for a smooth wire-bonding process. In a case where a through electrode is provided in the semiconductor substrate, it is possible to prevent the light-transmissive adhesive from flowing around to the side surface of the semiconductor substrate, and it is possible to suppress a defective connection, and the like. Thus, with the example method for manufacturing an optical device, it is possible to manufacture an optical device of a direct attachment structure having a reduced size, a high sensitivity and desirable performance.

An electrode pad may be provided on a same surface as the device region of the semiconductor substrate provided in the step (a); and the concave portion may be provided on an inner side of the electrode pad.

The method may further include the step of (d) forming a protruding portion on a region of the light-transmissive flattening film that is between the concave portion and the electrode pad, after the step (b) and before the step (c), wherein in the step (c), the light-transmissive member is formed on the light-transmissive adhesive layer and the protruding portion.

A plurality of the electrode pads may be provided in a row or rows; in the step (b), the concave portion may be formed so as to extend along the row or rows of the electrode pads; and in the step (d), the protruding portion may be formed so as to extend along the row or rows of the electrode pads.

A planar shape of the semiconductor substrate may be rectangular; and the electrode pads may be provided along one or more sides of the semiconductor substrate.

In the step (b), a portion of the light-transmissive flattening film that is located along a side of the semiconductor substrate where the electrode pads are absent and that is located on an outer side of the device region may also be removed to form the concave portion.

The electrode pads may be provided along two opposing sides of the semiconductor substrate.

The semiconductor substrate provided in the step (a) may include a through electrode running through the semiconductor substrate.

The concave portion may be provided on an outer side of the light-transmissive member bonded in the step (c).

The method may further include the step of (e) forming a protruding portion on a region of the light-transmissive flattening film that is on an outer side of the concave portion, after the step (b) and before the step (c), wherein in the step (c), the light-transmissive member is formed on the light-transmissive adhesive layer and the protruding portion.

An inner surface of the first concave portion may be tapered in the step (b).

With the example optical device and the example method for manufacturing the same, it is possible to suppress adhesion of the light-transmissive adhesive layer onto the edge portion or the side surface of the semiconductor substrate, whereby it is possible to reduce the size of the optical device and to improve the sensitivity thereof.

### BRIEF DESCRIPTION OF THE DRAWINGS

FIG. 1 is a perspective view showing a configuration of a solid-state imaging device according to a first embodiment.

FIG. 2A is a plan view showing a configuration of the solid-state imaging device of the first embodiment, and FIG. 2B is a cross-sectional view taken along line IIb-IIb in FIG. 2A.

FIG. 3 is a flow chart showing a method for manufacturing the solid-state imaging device of the first embodiment.

FIG. 4 is a perspective view showing a configuration of solid-state imaging device of a second embodiment.

FIG. 5A is a plan view showing a configuration of the solid-state imaging device of the second embodiment, and FIG. 5B is a cross-sectional view taken along line Vb-Vb in FIG. 5A.

FIG. 6 is a flow chart showing a method for manufacturing the solid-state imaging device of the second embodiment.

FIGS. 7A-7E are cross-sectional views showing a method for manufacturing the solid-state imaging device of the second embodiment.

FIG. 8 is a cross-sectional view showing a configuration of a solid-state imaging device of a third embodiment.

FIG. 9A is a plan view showing a configuration of an LED device of a fourth embodiment, and FIG. 9B is a cross-sectional view taken along line IXb-IXb in FIG. 9A.

FIG. 10A is a plan view showing a configuration of an important part of the LED device shown in FIG. 9A, and FIG. 10B is a cross-sectional view taken along line Xb-Xb in FIG. 10A.

FIGS. 11A-11C are cross-sectional views showing solid-state imaging devices according to first to third examples of a fifth embodiment.

FIG. 12 is a cross-sectional view showing a configuration of a solid-state imaging device according to a sixth embodiment.

FIG. 13 is a cross-sectional view showing a configuration of a conventional solid-state imaging device.

FIG. 14 is a perspective view showing a configuration of a conventional solid-state imaging device.

FIG. 15A is a plan view showing a problem with the conventional solid-state imaging device, and FIG. 15B is a cross-sectional view taken along line XVb-XVb in FIG. 15A.

FIG. 16 is a perspective view showing a configuration of a conventional solid-state imaging device.

FIG. 17 is a cross-sectional view showing the configuration of the conventional solid-state imaging device.

FIG. 18A is a plan view showing a problem with the conventional solid-state imaging device, and FIG. 18B is a cross-sectional view taken along line XVIIIb-XVIIIb in FIG. 18A.

### DESCRIPTION OF THE PREFERRED EMBODIMENTS

Example embodiments will now be described with reference to the drawings.

### FIRST EMBODIMENT

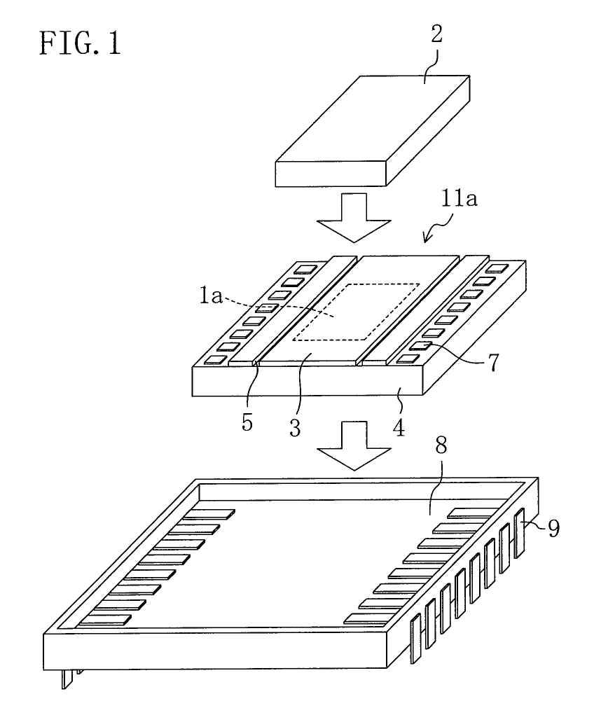

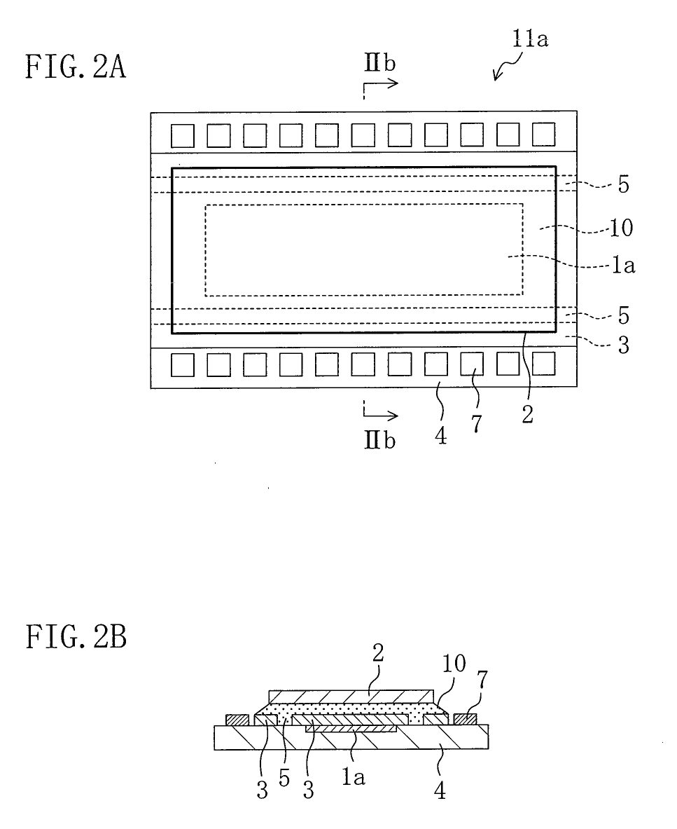

In a first embodiment, a solid-state imaging device will be described as an example optical device. FIG. 1 is a perspective view showing a configuration of a solid-state imaging device of the present embodiment. FIG. 2A is a plan view showing a configuration of the solid-state imaging device of the present embodiment, and FIG. 2B is a cross-sectional view taken along line IIb-IIb in FIG. 2A.

As shown in FIGS. 1, 2A and 2B, the solid-state imaging device of the present embodiment includes a solid-state imaging element 11a, a light-transmissive adhesive layer 10, and a light-transmissive member 2. The solid-state imaging element 11a includes a semiconductor substrate 4 with a light-receiving region (device region) 1a formed thereon, a plurality of electrode pads 7 formed along edge portions of the semiconductor substrate 4, concave portions 5 extending between the light-receiving region 1a and the electrode pads 7 as viewed from above, and a light-transmissive insulating film (light-transmissive flattening film) 3 formed on the semiconductor substrate 4 so as to cover the light-receiving region 1a. The light-transmissive adhesive layer 10 is provided on the semiconductor substrate 4 and the light-transmissive insulating film 3. The light-transmissive member 2 is bonded on the light-transmissive adhesive layer 10, and covers the light-receiving region 1a of the solid-state imaging element 11a as viewed from above. In the solid-state imaging device of the present embodiment, the solid-state imaging element 11a with the light-transmissive member 2 bonded thereto is placed on a package substrate 8 provided with a plurality of leads 9, as shown in FIG. 1. The end surface of the light-transmissive adhesive layer 10 is located between the electrode pads 7 and the light-transmissive member 2 as viewed from above.

As shown in FIG. 2B, the solid-state imaging device of the present embodiment includes the light-transmissive insulating film 3 with the concave portions 5 formed therein, and the concave portions 5 are filled with the light-transmissive adhesive layer 10. With this configuration, since the concave portions 5 are each formed in a region between the light-receiving region 1a and the electrode pads 7 as viewed from above, a portion of the light-transmissive adhesive that flows onto peripheral portion of the light-transmissive member 2 runs into the concave portions 5 when the light-transmissive member 2 is directly bonded onto the light-transmissive insulating film 3. Therefore, it is possible to prevent the light-transmissive adhesive from flowing onto the electrode pads 7. As a result, according to the present embodiment, it is possible to realize an optical device of a direct attachment structure having a reduced size, a high sensitivity and desirable performance, while suppressing adhesion of the light-transmissive adhesive layer 10 onto the electrode pads 7.

In the solid-state imaging device of the present embodiment, the concave portions 5 extend along the lines of the electrode pads 7. The dimensions such as the width and the depth of the concave portions 5 can be set by taking into consideration the amount of the light-transmissive adhesive to be applied and the physical properties such as the viscosity, and can be set to have a sufficient capacity so that the light-transmissive adhesive is prevented from flowing out onto the electrode pads 7. Although the electrode pads 7 are formed in the edge portions along two opposing sides of the semiconductor substrate 4 in the solid-state imaging device of the present embodiment, the present invention is not limited to this. The position of the concave portions 5 can be determined so that they are each located between the electrode pads 7 and the light-receiving region I a as viewed from above, depending on the positions of the electrode pads 7.

Although the light-transmissive insulating film 3 provided with the concave portions 5 is formed in the solid-state imaging device of the present embodiment, the light-transmissive insulating film 3 does not need to be electrically insulative as long as it is transmissive to light.

In the solid-state imaging device of the present embodiment, it is possible to improve the efficiency with which light is incident on the light-receiving region 1a by appropriately adjusting the thickness of the light-transmissive insulating film 3.

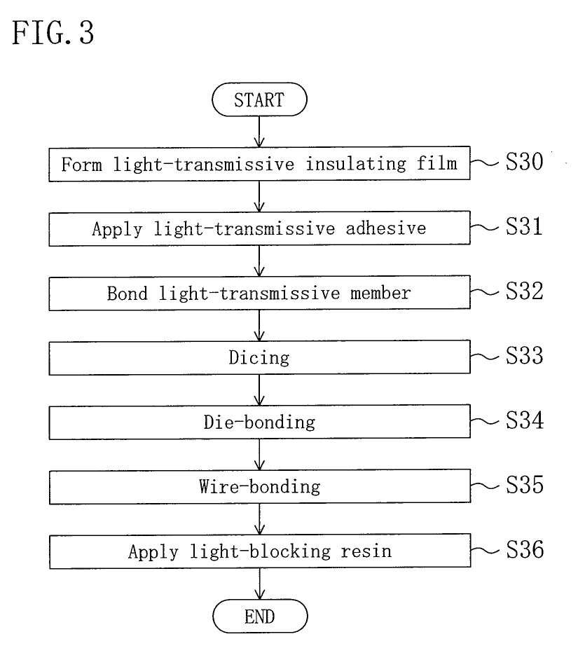

Next, a method for manufacturing the solid-state imaging device of the present embodiment will be described with reference to FIG. 3. FIG. 3 is a flow chart showing the method for manufacturing the solid-state imaging device of the present embodiment.

As shown in FIG. 3, first in the method for manufacturing the solid-state imaging device of the present embodiment, a plurality of solid-state imaging elements 11a, each including the light-receiving region 1a and the electrode pads 7 provided on the semiconductor substrate 4, are provided in step S30. The solid-state imaging elements 11a are provided adjacent to one another. Then, the light-transmissive insulating film 3 having a thickness of, for example, about 10 μm and made of an organic material, or the like, is formed on the semiconductor substrate 4 so as to cover the light-receiving region I a in each of the solid-state imaging elements 11a.

Then, portions of the light-transmissive insulating film 3 that are each located between the electrode pads 7 and the light-receiving region 1a as viewed from above are selectively removed to thereby form the concave portions 5 in the light-transmissive insulating film 3. A specific method for forming the concave portions 5 may include depositing a resist after forming the light-transmissive insulating film 3 on the semiconductor substrate 4, and then selectively removing portions of the light-transmissive insulating film 3 to be the concave portions by an etching process using the resist as a mask.

Then, in step S31, a light-transmissive adhesive in the liquid form is applied on the semiconductor substrate 4 and the light-transmissive insulating film 3. Then, in step S32, the light-transmissive member 2 is placed on the light-transmissive adhesive so as to cover the light-receiving region 1a as viewed from above. Thus, the light-transmissive adhesive layer 10 obtained by curing the light-transmissive adhesive is formed on the light-transmissive insulating film 3, and the light-transmissive member 2 is bonded to the light-transmissive insulating film 3 with the light-transmissive adhesive layer 10 interposed therebetween. The concave portions 5 provided in the light-transmissive insulating film 3 are filled with the light-transmissive adhesive layer 10.

Then, in step S33, the collection of solid-state imaging elements 11a obtained in step S32 is diced into individual pieces. Then, in step S34, each individual solid-state imaging element 11a is die-bonded to the package substrate 8 provided with the leads 9. Then, in step S35, the leads 9 are wire-bonded to the electrode pads 7 provided on the solid-state imaging element 11a. Then, in step S36, a light-blocking resin 13 is applied across the semiconductor substrate 4 except for the upper surface of the light-transmissive member 2, thereby packaging the solid-state imaging element 11a. With the method described above, it is possible to manufacture the solid-state imaging device of the present embodiment.

According to the method for manufacturing the solid-state imaging device of the present embodiment, the light-transmissive insulating film 3 with the concave portions 5 therein is formed in step S30. In this method, the concave portions 5 are each formed in a region of the light-transmissive insulating film 3 between the light-receiving region 1a and the electrode pads 7 as viewed from above, whereby even if the light-transmissive adhesive flows onto a peripheral portion of the light-transmissive member 2 in step S32, the overflowing portion of the light-transmissive adhesive can be held in the concave portions 5. Therefore, it is possible to prevent the light-transmissive adhesive from flowing onto the electrode pads 7. As a result, in the process of wire-bonding the electrode pads 7 and the leads 9 to each other in step S35, for example, problems such as a defective connection are suppressed, thereby allowing for a smooth wire-bonding process. Therefore, with the method for manufacturing the optical device of the present embodiment, it is possible to manufacture an optical device of a direct attachment structure having a reduced size, a high sensitivity and desirable performance, while suppressing adhesion of the light-transmissive adhesive layer 10 onto the electrode pads 7.

If the amount of light-transmissive adhesive to be applied in step S31 is reduced, the light-transmissive adhesive 10 is prevented from flowing onto the electrode pads 7. In such a case, however, the light-transmissive adhesive may not spread to reach under the four corners of the light-transmissive member 2. Then, due to the difference in refractive index between the air and the light-transmissive adhesive layer 10, the light transmission for incident light of the central portion of the light-receiving region 1a is different from that in the edge portion of the light-receiving region 1a. With the solid-state imaging device of the present embodiment, the concave portions 5 are provided in the light-transmissive insulating film 3, whereby it is possible to prevent the light-transmissive adhesive 10 from adhering to the electrode pads 7 even when a sufficient amount of the light-transmissive adhesive 10 is applied. Thus, in the solid-state imaging device of the present embodiment, the light transmission for incident light is made uniform across the light-receiving region 1a, whereby it is possible to obtain desirable images.

Moreover, with the method for manufacturing the solid-state imaging device of the present embodiment, it is possible to obtain a solid-state imaging device of a direct attachment structure which is packaged by resin encapsulation, whereby it is possible to eliminate problems such as dust being mixed in the light-receiving region 1a during the manufacturing process. Therefore, using the method for manufacturing the solid-state imaging device of the present embodiment, it is possible to realize a semiconductor device having a reduced size and a high reliability.

### SECOND EMBODIMENT

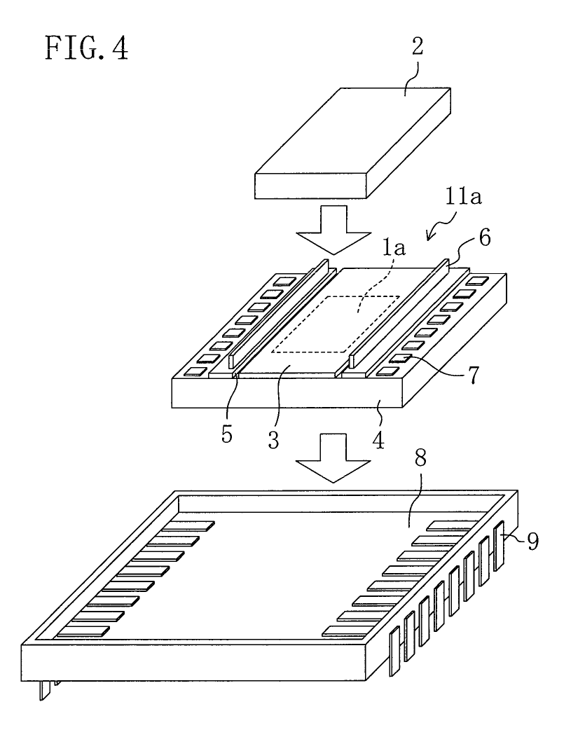

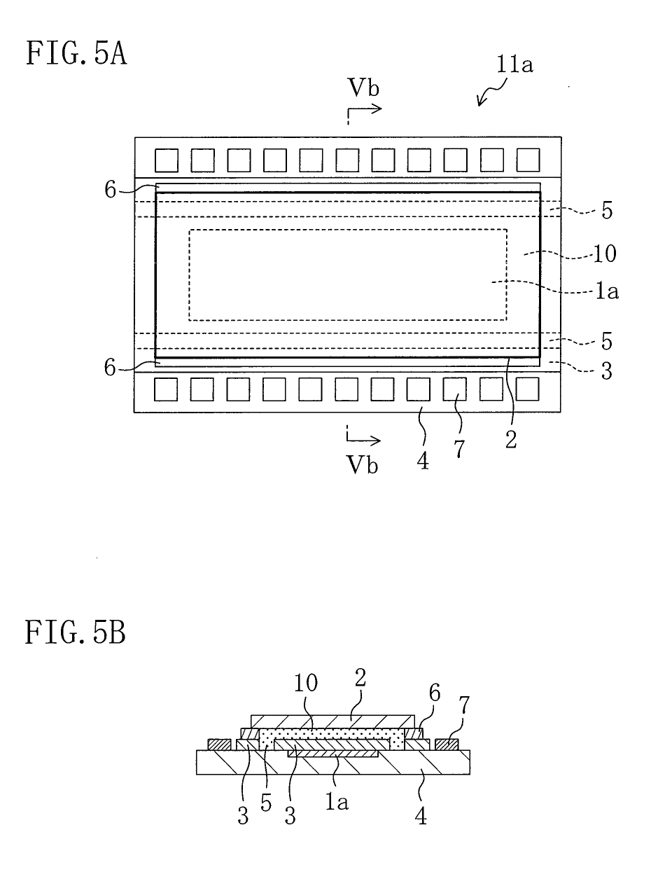

In a second embodiment, a solid-state imaging device will be described as an example optical device. FIG. 4 is a perspective view showing a configuration of a solid-state imaging device of the present embodiment. FIG. 5A is a plan view showing a configuration of the solid-state imaging device of the present embodiment, and FIG. 5B is a cross-sectional view taken along line Vb-Vb in FIG. 5A.

As shown in FIGS. 4, 5A and 5B, the solid-state imaging device of the present embodiment includes the solid-state imaging element 11a, the light-transmissive adhesive layer 10, and the light-transmissive member 2. The solid-state imaging element 11a includes the semiconductor substrate 4 with the light-receiving region 1a formed thereon, the electrode pads 7 formed along edge portions of the semiconductor substrate 4, the concave portions 5 extending between the light-receiving region 1a and the electrode pads 7 as viewed from above, the light-transmissive insulating film 3 formed on the semiconductor substrate 4 so as to cover the light-receiving region 1a, and protruding portions 6 provided on the light-transmissive insulating film 3 so as to extend between the concave portions 5 and the electrode pads 7 as viewed from above. The light-transmissive adhesive layer 10 is provided on the semiconductor substrate 4 and the light-transmissive insulating film 3, and fills the concave portions 5. The light-transmissive member 2 is bonded on the light-transmissive adhesive layer 10 and the protruding portions 6, and covers the light-receiving region 1a of the solid-state imaging element 11a as viewed from above. In the solid-state imaging device of the present embodiment, the solid-state imaging element 11a with the light-transmissive member 2 bonded thereto is placed on the package substrate 8 provided with the leads 9, as shown in FIG. 4.

As shown in FIG. 5B, the solid-state imaging device of the present embodiment includes the light-transmissive insulating film 3 with the concave portions 5 formed therein, and the protruding portions 6 formed on the light-transmissive insulating film 3, and the concave portions 5 are filled with the light-transmissive adhesive layer 10. With this configuration, since the concave portions 5 are each formed in a region between the light-receiving region 11a and the electrode pads 7 as viewed from above, a portion of the light-transmissive adhesive that flows onto a peripheral portion of the light-transmissive member 2 runs into the concave portions 5 when the light-transmissive member 2 is directly bonded onto the light-transmissive insulating film 3. Therefore, it is possible to prevent the light-transmissive adhesive from flowing onto the electrode pads 7. Moreover, the solid-state imaging device of the present embodiment includes the protruding portions 6 each provided in a region between the concave portions 5 and the electrode pads 7 as viewed from above, whereby even if the light-transmissive adhesive flows further out beyond the concave portions 5, the flow of the light-transmissive adhesive can be blocked by the protruding portions 6. Therefore, according to the present embodiment, it is possible to realize an optical device of a direct attachment structure having a reduced size, a high sensitivity and desirable performance, while reliably suppressing adhesion of the light-transmissive adhesive layer 10 onto the electrode pads 7.

In the solid-state imaging device of the present embodiment, the concave portions 5 and the protruding portions 6 extend along the lines of the electrode pads 7. The dimensions such as the width and the height (depth) of the concave portions 5 and the protruding portions 6 can be set by taking into consideration the amount of the light-transmissive adhesive to be applied and the physical properties such as the viscosity. The dimensions of the concave portions 5 can be set to have a sufficient capacity so that the light-transmissive adhesive is prevented from flowing out onto the electrode pads 7. Since the solid-state imaging device of the present embodiment includes both the concave portions 5 and the protruding portions 6, a large portion of the light-transmissive adhesive that is flowing out can be held in the concave portions 5, and the protruding portions 6 are only required to have a sufficient height for blocking the flow of a portion of the light-transmissive adhesive that flows further out beyond the concave portions 5. Therefore, it is possible to obtain a sufficient effect without providing the protruding portions 6 which are very high, and it is possible to sufficiently accommodate the need for reducing the size of the optical device.

Although the electrode pads 7 are formed in the edge portions along two opposing sides of the semiconductor substrate 4 in the solid-state imaging device of the present embodiment, the example embodiment is not limited to this. The position of the concave portions 5 can be determined so that they are each located between the electrode pads 7 and the light-receiving region 1a as viewed from above, depending on the positions of the electrode pads 7.

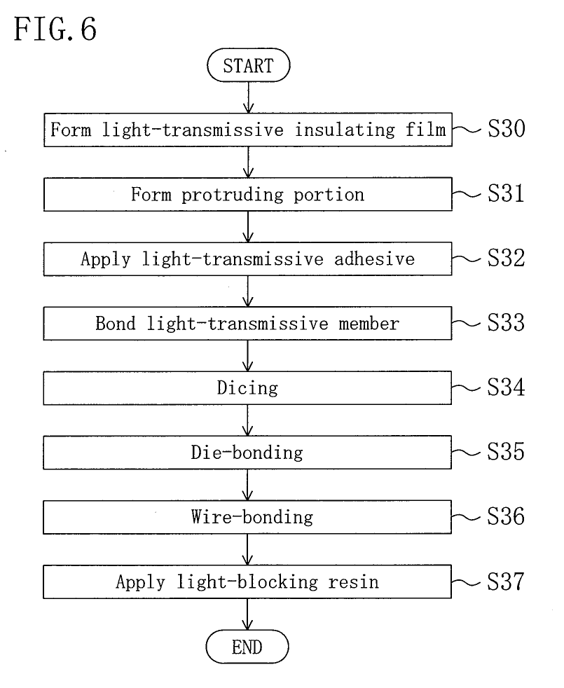

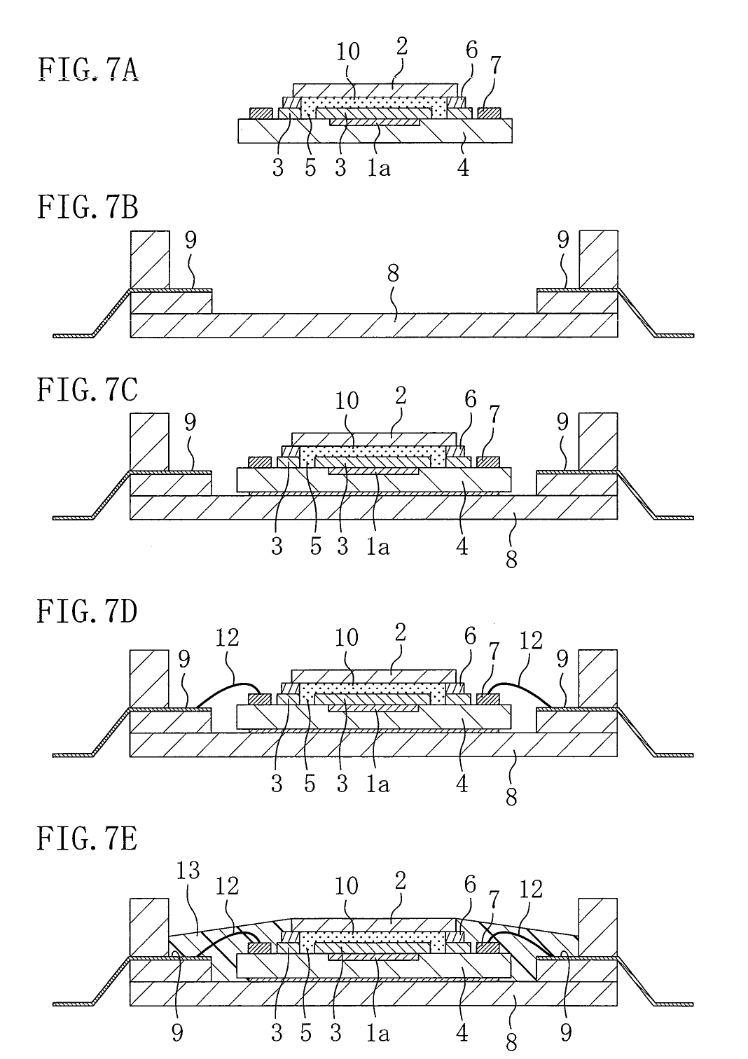

Next, a method for manufacturing the solid-state imaging device of the present embodiment will be described with reference to FIGS. 6 and 7A to 7E. FIG. 6 is a flow chart showing the method for manufacturing the solid-state imaging device of the present embodiment. FIGS. 7A to 7E are cross-sectional views showing the method for manufacturing the solid-state imaging device of the present embodiment.

As shown in FIG. 6, first in the method for manufacturing the solid-state imaging device of the present embodiment, a plurality of solid-state imaging elements 11a, each including the light-receiving region 1a and the electrode pads 7 provided on the semiconductor substrate 4, are provided in step S30. The solid-state imaging elements 11a are provided adjacent to one another. Then, the light-transmissive insulating film 3 having a thickness of, for example, about 10 μm and made of an organic material, or the like, is formed on the semiconductor substrate 4 so as to cover the light-receiving region 1a in each of the solid-state imaging elements 11a.

Then, portions of the light-transmissive insulating film 3 that are each located between the electrode pads 7 and the light-receiving region 1a as viewed from above are selectively removed to thereby form the concave portions 5 in the light-transmissive insulating film 3. A specific method for forming the concave portions 5 may include depositing a resist after forming the light-transmissive insulating film 3 on the semiconductor substrate 4, and then selectively removing portions of the light-transmissive insulating film 3 to be the concave portions by an etching process using the resist as a mask.

Then, in step S31, the protruding portions 6 of a photosensitive material, or the like, are formed in a region on the light-transmissive insulating film 3 between the concave portions 5 and the electrode pads 7 as viewed from above. A specific method for forming the protruding portions 6 may include applying a photosensitive material of, for example, an acrylate, or the like, on the light-transmissive insulating film 3, and then forming an acrylate mask. Then, portions of the photosensitive material except for portions to be the protruding portions are selectively removed by a photography technique using the acrylate mask, thereby forming the protruding portions 6.

Then, in step S32, a light-transmissive adhesive in the liquid form is applied on the semiconductor substrate 4, the light-transmissive insulating film 3, and the protruding portions 6. Then, in step S33, the light-transmissive member 2 is placed on the light-transmissive adhesive so as to cover the light-receiving region 1a as viewed from above. Thus, the light-transmissive adhesive layer 10 obtained by curing the light-transmissive adhesive is formed on the light-transmissive insulating film 3, and the light-transmissive member 2 is bonded to the light-transmissive insulating film 3 with the light-transmissive adhesive layer 10 and the protruding portions 6 interposed therebetween. The concave portions 5 provided in the light-transmissive insulating film 3 are filled with the light-transmissive adhesive layer 10.

Then, in step S34, the collection of solid-state imaging elements 11a obtained in step S33 is diced into individual pieces, as shown in FIG. 7A.

Then, in step S35, the package substrate 8 having the leads 9 thereon is provided, as shown in FIG. 7B. Then, in step S36, each individual solid-state imaging element 11a is die-bonded to the package substrate 8, as shown in FIG. 7C.

Then, in step S37, the leads 9 are wire-bonded to the electrode pads 7 provided on the solid-state imaging element 11a using wires 12, as shown in FIG. 7C. Then, in step S38, the light-blocking resin 13 is applied across the semiconductor substrate 4 except for the upper surface of the light-transmissive member 2, thereby packaging the solid-state imaging element, as shown in FIG. 7D. With the method described above, it is possible to manufacture the solid-state imaging device of the present embodiment.

According to the method for manufacturing the solid-state imaging device of the present embodiment, the light-transmissive insulating film 3 with the concave portions 5 therein is formed in step S30, and the protruding portions 6 are formed in step S31. In this method, the concave portions 5 are each formed in a region of the light-transmissive insulating film 3 between the light-receiving region 1a and the electrode pads 7 as viewed from above, whereby even if the light-transmissive adhesive flows onto a peripheral portion of the light-transmissive member 2 in step S32, the overflowing portion of the light-transmissive adhesive can be held in the concave portions 5. Moreover, in the method for manufacturing the present embodiment, the protruding portions 6 are each formed in a region between the concave portions 5 and the electrode pads 7 as viewed from above in step S33, whereby even if the light-transmissive adhesive flows further out beyond the concave portions 5, the flow of the light-transmissive adhesive can be blocked by the protruding portions 6. Therefore, it is possible to prevent the light-transmissive adhesive from flowing onto the electrode pads 7. As a result, in the process of wire-bonding the electrode pads 7 and the leads 9 to each other in step S37, for example, problems such as a defective connection are suppressed, thereby allowing for a smooth wire-bonding process. Therefore, with the method for manufacturing the optical device of the present embodiment, it is possible to manufacture an optical device of a direct attachment structure having a reduced size, a high sensitivity and desirable performance, while reliably preventing the adhesion of the light-transmissive adhesive layer 10 onto the electrode pads 7.

Moreover, with the method for manufacturing the solid-state imaging device of the present embodiment, it is possible to obtain a solid-state imaging device of a direct attachment structure which is packaged by resin encapsulation in steps shown in FIGS. 7A-7D, whereby it is possible to eliminate problems such as dust being mixed in the light-receiving region 1a during the manufacturing process. Therefore, using the method for manufacturing the solid-state imaging device of the present embodiment, it is possible to realize a semiconductor device having a reduced size and a high reliability.

### THIRD EMBODIMENT

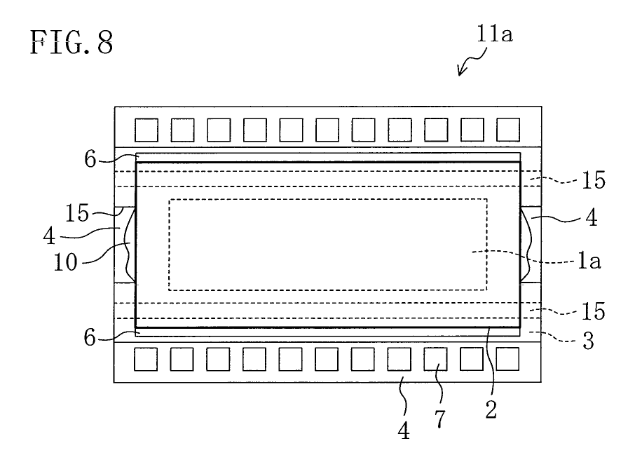

In a third embodiment, a solid-state imaging device will be described as an example optical device. The configuration of the solid-state imaging device of the present embodiment differs only partly from that of the solid-state imaging device of the second embodiment, and therefore similar portions will not be described below in detail. FIG. 8 is a plan view showing a configuration of the solid-state imaging device of the present embodiment.

As shown in FIG. 8, the solid-state imaging device of the present embodiment includes the solid-state imaging element 11a, the light-transmissive adhesive layer 10, and the light-transmissive member 2. The solid-state imaging element 11a includes the semiconductor substrate 4 with the light-receiving region 1a formed thereon, the electrode pads 7 formed along edge portions of the semiconductor substrate 4, the light-transmissive insulating film 3 including concave portions 15 and formed on the semiconductor substrate 4 so as to cover the light-receiving region 1a, and the protruding portions 6 provided on the light-transmissive insulating film 3 so as to extend between the concave portion 15 and the electrode pads 7 as viewed from above. The light-transmissive adhesive layer 10 is provided on the semiconductor substrate 4 and the light-transmissive insulating film 3, and fills the concave portions 15. The light-transmissive member 2 is bonded on the light-transmissive adhesive layer 10, and covers the light-receiving region 1a of the solid-state imaging element 11a as viewed from above. Although not shown in the figures, in the solid-state imaging device of the present embodiment, the solid-state imaging element 11a with the light-transmissive member 2 bonded thereto is placed on the package substrate 8 provided with the leads 9, as is in the solid-state imaging device of the second embodiment (see FIG. 4).

In the solid-state imaging device of the present embodiment, the concave portions 15 are formed in a region (first region) of the light-transmissive insulating film 3 between the light-receiving region 1a and the electrode pads 7 as viewed from above, and also in a region (second region) of the light-transmissive insulating film 3 located on the outer side of the light-receiving region 1a and along those sides of the semiconductor substrate 4 where the electrode pads 7 are absent. At least the concave portions 15 formed in the first region are filled with the light-transmissive adhesive layer 10.

According to the solid-state imaging device of the present embodiment, the concave portions 15 are formed not only in the first region, but also in the second region which is along those sides of the semiconductor substrate 4 where the electrode pads 7 are absent. With this configuration, even if a large amount of the light-transmissive adhesive flows over toward the outside of the semiconductor substrate when fixing the light-transmissive member 2 by pressing the light-transmissive member 2 onto the light-transmissive adhesive, the light-transmissive adhesive can be held in the concave portion 15 formed in the second region where the electrode pads 7 are absent. Therefore, it is possible to more reliably prevent the light-transmissive adhesive from flowing onto the electrode pads 7.

The solid-state imaging device of the present embodiment has a configuration where the solid-state imaging device is further provided with the concave portions 15 in addition to the protruding portions 6. This is preferred because even if the light-transmissive adhesive flows around the side surface of the protruding portions 6 extending along the lines of the electrode pads 7 at opposite end portions of the protruding portions 6, it is possible to effectively suppress the overflow of the light-transmissive adhesive onto the electrode pads. The example embodiment is not limited to this, and effects similar to those of the solid-state imaging device of the present embodiment can be obtained even with a solid-state imaging device that is not provided with the protruding portions 6, by forming the concave portions 15 in regions corresponding to the first region and the second region of the present embodiment.

Although not shown in the figures, the solid-state imaging device of the present embodiment shown in FIG. 8 can be manufactured by partially changing the method for manufacturing the solid-state imaging device of the second embodiment. Specifically, in step S30 shown in FIG. 6, the light-transmissive insulating film 3 is formed on the semiconductor substrate 4 so as to cover the light-receiving region 1a of the solid-state imaging element 11a, as is in the manufacturing method of the second embodiment. Then, the concave portions 15 are formed by selectively removing portions of the light-transmissive insulating film 3 that are located between the electrode pads 7 and the light-receiving region 1a as viewed from above and portions of the light-transmissive insulating film 3 that are located on the outer side of the light-receiving region 1a and along those sides of the semiconductor substrate 4 where the electrode pads 7 are absent. By successively performing steps S31-S37 thereafter, the solid-state imaging device of the present embodiment can be manufactured.

### FOURTH EMBODIMENT

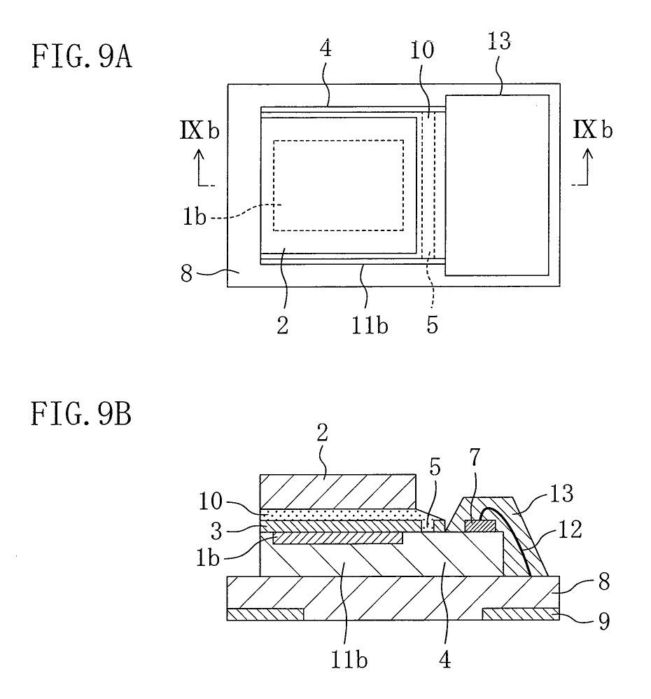

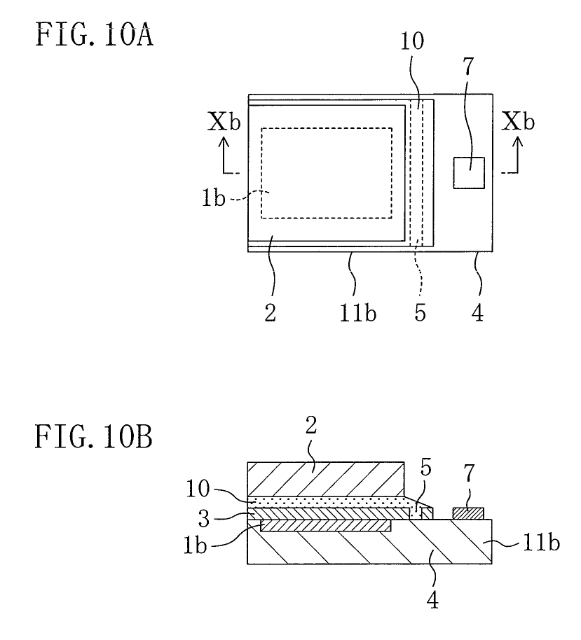

In a fourth embodiment of the present invention, an LED (Light Emitting Diode) device will be described as an example optical device. FIG. 9A is a plan view showing a configuration of the LED device of the present embodiment, and FIG. 9B is a cross-sectional view taken along line IXb-IXb in FIG. 9A. FIG. 10A is a plan view showing a configuration of an important part of the LED device shown in FIG. 9A, and FIG. 10B is a cross-sectional view taken along line Xb-Xb in FIG. 10A.

As shown in FIGS. 9A, 9B, 10A and 10B, the LED device of the present embodiment includes an LED element 11b. The LED element 11b includes the semiconductor substrate 4 with a light-emitting region lb formed thereon, the electrode pads 7 formed along edge portions of the semiconductor substrate 4, the concave portion 5 provided between the light-emitting region lb and the electrode pads 7 as viewed from above, and the light-transmissive insulating film 3 formed on the semiconductor substrate 4 so as to cover the light-emitting region 1b. Moreover, the LED device of the present embodiment includes the light-transmissive adhesive layer 10 provided on the semiconductor substrate 4 and the light-transmissive insulating film 3, and the light-transmissive member 2 bonded on the light-transmissive adhesive layer 10 so as to cover the light-emitting region 1b of the LED element 11b as viewed from above. In the LED device of the present embodiment, the LED element 11b with the light-transmissive member 2 bonded thereto is placed on the package substrate 8 provided with the leads 9, as shown in FIGS. 9A and 9B. The end surface of the light-transmissive adhesive layer 10 is located between the electrode pads 7 and the light-transmissive member 2 as viewed from above.

The LED device of the present embodiment includes the light-transmissive insulating film 3 with the concave portion 5 formed therein, and the concave portion 5 is filled with the light-transmissive adhesive layer 10, as shown in FIGS. 10A and 10B. With this configuration, since the concave portion 5 is provided in a region between the light-emitting region 1b and the electrode pads 7 as viewed from above, a portion of the light-transmissive adhesive that flows onto a peripheral portion of the light-transmissive member 2 runs into the concave portion 5 when the light-transmissive member 2 is directly bonded onto the light-transmissive insulating film 3. Therefore, it is possible to prevent the light-transmissive adhesive from flowing onto the electrode pads 7. As a result, according to the present embodiment, it is possible to realize an optical device having a reduced size and desirable performance, while suppressing adhesion of the light-transmissive adhesive layer 10 onto the electrode pads 7.

The concave portion 5 may be provided on the outer side of the light-transmissive member 2 as is in the LED device of the present embodiment. With such a configuration, as compared with a configuration where the concave portion 5 is provided inside the edge of the light-transmissive member 2, there is an increased distance over which the light-transmissive adhesive needs to flow to reach the concave portion 5 when the light-transmissive member 2 is placed onto the semiconductor substrate 4 after the light-transmissive adhesive is applied. This weakens the current of the light-transmissive adhesive flowing into the concave portion 5. Therefore, the light-transmissive adhesive is less likely to flow over the concave portion 5, whereby it is possible to more reliably suppress the overflow of the light-transmissive adhesive onto the electrode pads 7.

While the first to third embodiments and the fourth embodiment are directed to a solid-state imaging device and an LED device, respectively, as an example optical device, the example embodiments are not limited thereto. Similar effects to those of the optical devices of the example embodiments can be realized also with an optical device including an image sensor (solid-state imaging element) such as a CCD and a CMOS, or a light receiving element such as a photodiode, a phototransistor or a photo IC. The first to third embodiments, which are directed to solid-state imaging devices, are useful in enhancing the performance of a camera module of a digital camera, a camera module of a mobile telephone or an on-vehicle camera, for example.

The example embodiments are also applicable to an optical device including a light emitting element such as an LED or a semiconductor laser. LEDs are used for a light-emitting display, a lighting module, and the like, of a mobile telephone, for example, whereas a semiconductor laser is suitably used in a BD (Blu-ray Disc), DVD (Digital Versatile Disc), or CD-ROM (Compact Disc Read Only Memory) drive.

### FIFTH EMBODIMENT

A fifth embodiment is directed to an example of a solid-state imaging device of any of the example embodiments described above, wherein through electrodes are provided instead of the electrode pads.

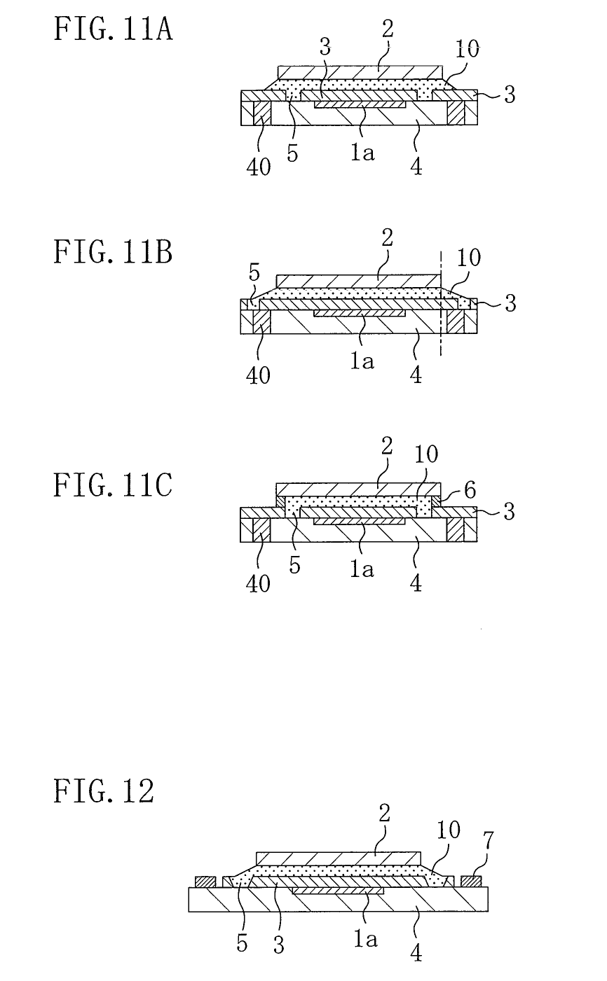

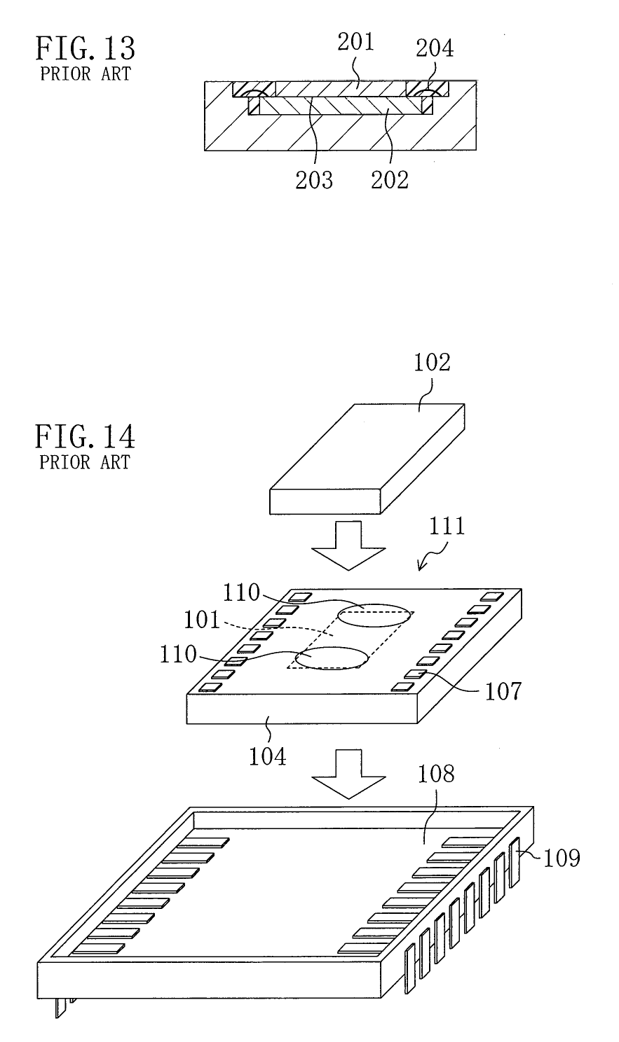

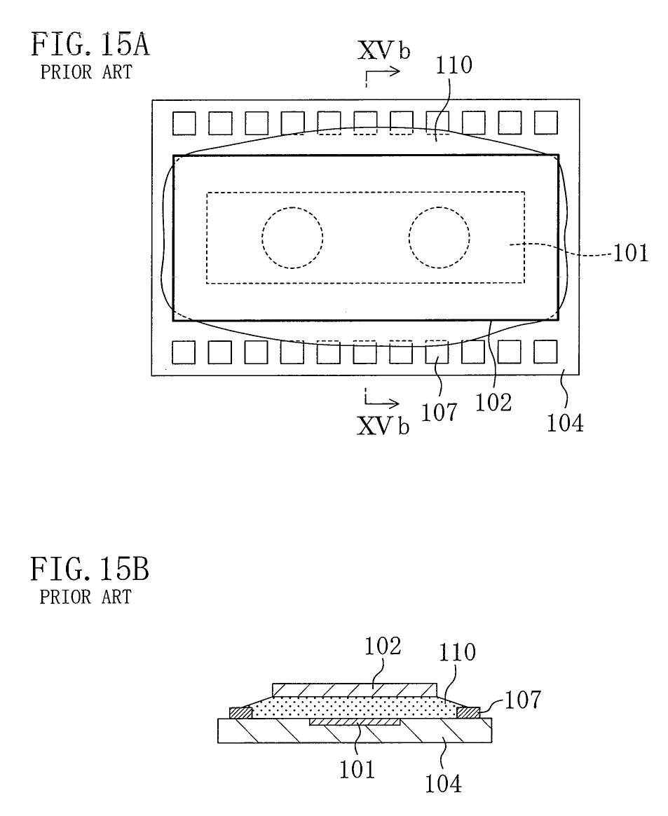

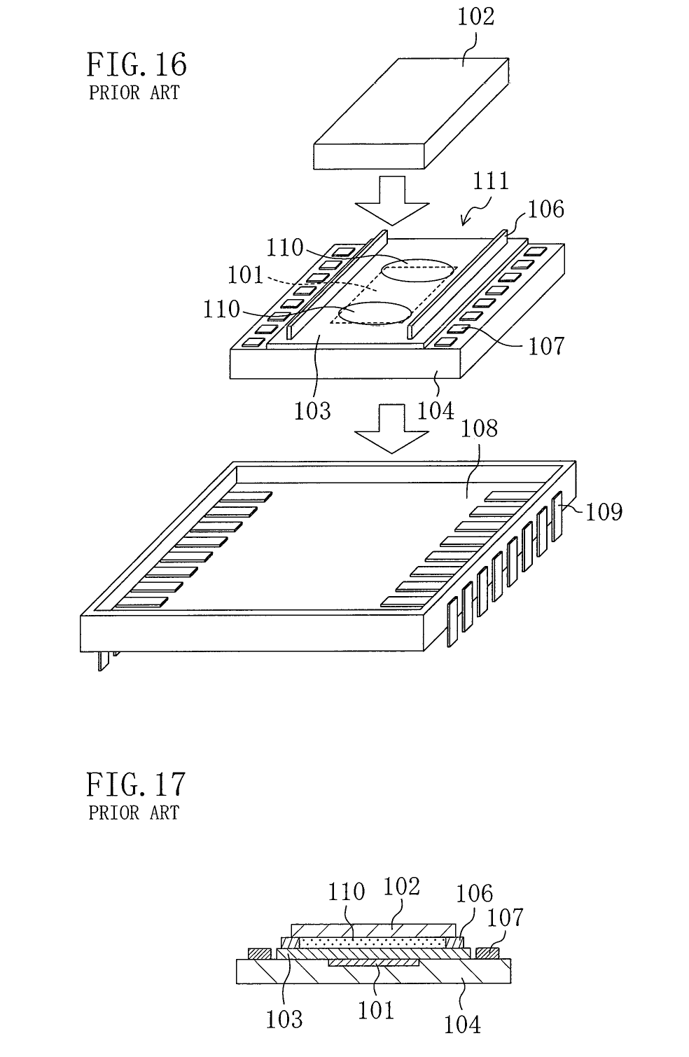

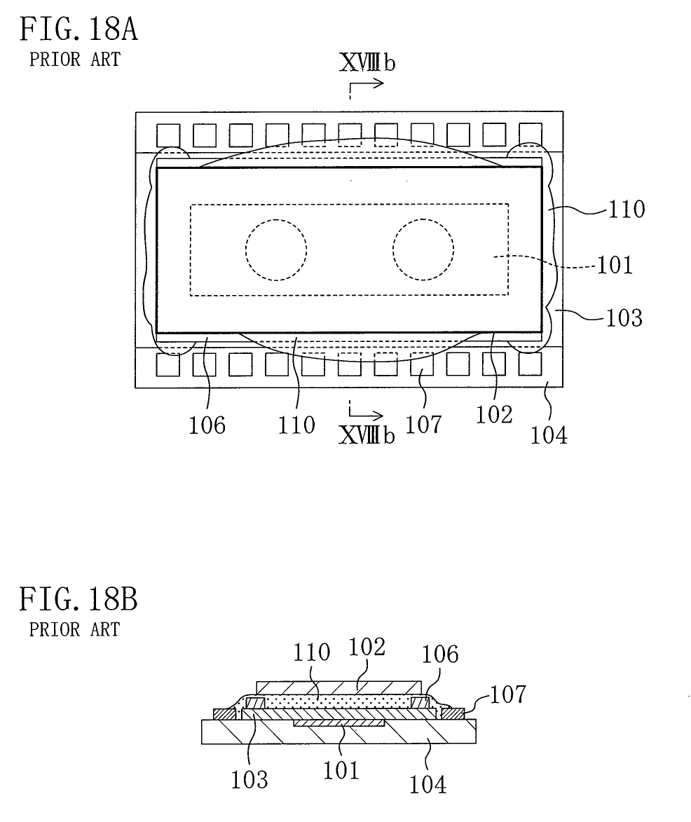

FIGS. 11A-11C are cross-sectional views showing solid-state imaging devices according to first to third examples of the present embodiment.

### First Example

In a solid-state imaging device according to a first example shown in FIG. 11A, through electrodes 40 are provided instead of the electrode pads 7 of the solid-state imaging device of the first embodiment shown in FIGS. 2A and 2B. In the solid-state imaging device of the present example, the light-transmissive insulating film 3 including the concave portions 5 therein is provided on the semiconductor substrate 4. The light-transmissive member 2 is bonded on the light-transmissive insulating film 3 with the light-transmissive adhesive layer 10 interposed therebetween, and the concave portions 5 are filled with the light-transmissive adhesive layer 10. On the reverse surface of the semiconductor substrate 4, there are provided a plurality of external terminals made of solder, or the like, electrically connected to the through electrodes 40 (not shown).

In the semiconductor substrate 4, the through electrode 40 is provided running through the semiconductor substrate 4 and connected to a circuit in the light-receiving region 1a. The through electrodes 40 may be provided in lines along edge portions of the semiconductor substrate 4, for example, as are the electrode pads 7.

In the solid-state imaging device of the present example, since the electrode pads 7 are not provided, the light-transmissive adhesive layer 10 may extend onto the edge portions of the semiconductor substrate 4. However, if the light-transmissive adhesive layer 10 extends around to the side surface of the semiconductor substrate 4, there may occur problems such as a defective connection on the lower surface of the through electrode 40. With the provision of the concave portions 5, it is possible to prevent the light-transmissive adhesive from flowing around to the side surface of the semiconductor substrate 4. Moreover, since the light-transmissive adhesive layer 10 can be provided over the through electrodes 40, it is possible to reduce the planar size of the solid-state imaging device as compared with a case where electrode pads are provided. Particularly, in the solid-state imaging device of the present example, the concave portions 5 are provided, whereby it is possible to decrease the margin for preventing the light-transmissive adhesive from flowing over to the side surface of the semiconductor substrate 4, and it is possible to reduce the planar size.

With the provision of the concave portions 5, it is easier to fill the gap between the light-transmissive insulating film 3 and the light-transmissive member 2 with the light-transmissive adhesive layer 10, whereby it is possible to make uniform the light transmission for light incident on the light-receiving region 1a.

In the present example, since the concave portions 5 are provided so as to overlap the edge portions of the light-transmissive member 2 as viewed from above, the area of adhesion between the light-transmissive member 2 and the light-transmissive insulating film 3 is increased and the adhesion strength of the light-transmissive member 2 can be improved, as compared with a case where the concave portions 5 are not provided. It is also possible to further improve the adhesion strength of the light-transmissive member 2 by increasing the area of the concave portions 5 or by increasing the number of the concave portions 5.

### Second Example

In a solid-state imaging device according to a second example shown in FIG. 11B, the concave portions 5 are each provided in a portion of the light-transmissive insulating film 3 that is located on the outer side of the light-transmissive member 2, as are in the LED device of the fourth embodiment shown in FIGS. 9A and 9B. The through electrodes 40 are provided instead of the electrode pads 7. Otherwise, the configuration of this example is substantially the same as that of the solid-state imaging device of the first embodiment, and thus will not be described below.

In the solid-state imaging device of the present example, the concave portions 5 are provided on the outer side of the light-transmissive member 2. Therefore, there is an increased distance over which the light-transmissive adhesive needs to flow to reach the concave portions 5 when the light-transmissive member is placed onto the semiconductor substrate 4 after the light-transmissive adhesive is applied. This weakens the current of the light-transmissive adhesive flowing into the concave portions 5. Therefore, the light-transmissive adhesive is less likely to flow over the concave portions 5, whereby it is possible to more reliably suppress the overflow of the light-transmissive adhesive onto the electrode pads 7.

Moreover, since the light-transmissive adhesive layer 10 can be placed so as to overlap the through electrodes 40 as viewed from above, it is possible to reduce the planar size of the solid-state imaging device as compared with a case where electrode pads are provided.

### Third Example

A solid-state imaging device according to a third example shown in FIG. 11C is similar to the solid-state imaging device of the second embodiment shown in FIG. 4, except that the through electrodes 40 running through the semiconductor substrate 4 are provided instead of the electrode pads 7.

In the solid-state imaging device of the present example, the light-transmissive insulating film 3 provided with the concave portions 5 is provided on the semiconductor substrate 4, and the wall-like protruding portions 6, for example, are provided on portions of the light-transmissive insulating film 3 that are located on the outer side of the concave portions 5. The concave portions 5 and the gap between the light-transmissive insulating film 3 and the light-transmissive member 2 are filled with the light-transmissive adhesive layer 10. Since the light-transmissive member 2 is mounted on the upper surface of the protruding portions 6, it is possible to maintain the light-transmissive member 2 to be precisely parallel to the upper surface of the semiconductor substrate 4 when bonding the light-transmissive member 2.

With the provision of the protruding portions 6, even if the light-transmissive adhesive flows over to the outside of the concave portions 5, the flow of the light-transmissive adhesive can be blocked by the protruding portions 6. Therefore, it is possible to more reliably prevent the light-transmissive adhesive from flowing around to the side surface of the semiconductor substrate 4. Moreover, with the provision of the through electrodes 40, it is possible to further reduce the size.

While through electrodes are provided in a solid-state imaging device including the light-receiving region 1a in each example of the present embodiment, through electrodes may be provided in an LED device or a laser device.

### SIXTH EMBODIMENT

FIG. 12 is a cross-sectional view showing a configuration of a solid-state imaging device according to a sixth embodiment. The solid-state imaging device of the present embodiment is characteristic in that the concave portions 5, which are provided in the light-transmissive insulating film 3 so as to extend between the light-receiving region la and the electrode pads 7, have a tapered inner surface, i.e., a decreasing width toward the bottom.

With this configuration, the light-transmissive adhesive more easily flows into the concave portions 5, whereby it is possible to effectively prevent the light-transmissive adhesive layer 10 from flowing onto the electrode pads 7.

More than one of the example embodiments and examples above can be combined together as long as doing so does not depart from the spirit of the present invention. For example, the concave portions 5 having a tapered inner surface may be provided in a solid-state imaging device having through electrodes.

The technique described above is useful in reducing the size of an optical device and in increasing the sensitivity thereof.

The foregoing description illustrates and describes the present disclosure. Additionally, the disclosure shows and describes only the preferred embodiments of the disclosure, but, as mentioned above, it is to be understood that it is capable of changes or modifications within the scope of the concept as expressed herein, commensurate with the above teachings and/or skill or knowledge of the relevant art. The described hereinabove are further intended to explain best modes known of practicing the invention and to enable others skilled in the art to utilize the disclosure in such, or other embodiments and with the various modifications required by the particular applications or uses disclosed herein. Accordingly, the description is not intended to limit the invention to the form disclosed herein. Also it is intended that the appended claims be construed to include alternative embodiments.

What is claimed is:

1. An optical device comprising:
a semiconductor substrate including a device region formed thereon, the device region including at least one of a light-receiving region and a light-emitting region;
a light-transmissive flattening film covering the device region, and including a first concave portion located in a region on an outer side of the device region;
a light-transmissive member formed on the light-transmissive flattening film; and
a light-transmissive adhesive layer bonding together the light-transmissive flattening film and the light-transmissive member, and filling the first concave portion.

2. The optical device of claim 1, further comprising:
an electrode pad provided on a portion of the semiconductor substrate that is located on a same surface as the device region and on an outer side of the device region, wherein
the first concave portion is formed between the device region and the electrode pad.

3. The optical device of claim 2, wherein an edge of the light-transmissive adhesive layer is located on the semiconductor substrate on an outer side of the light-transmissive member and on an inner side of the electrode pad.

4. The optical device of claim 2, further comprising:
a protruding portion provided in a region on the light-transmissive flattening film that is between the first concave portion and the electrode pad, wherein
the light-transmissive member is placed on the protruding portion.

5. The optical device of claim 4, wherein
a plurality of the electrode pads are provided in a row or rows; and
the first concave portion and the protruding portion are each formed so as to extend along the row or rows of the electrode pads.

6. The optical device of claim 2, wherein
a planar shape of the semiconductor substrate is rectangular; and
the electrode pads are provided along one or more sides of the semiconductor substrate.

7. The optical device of claim 6, wherein
a second concave portion is formed in a portion of the light-transmissive flattening film that is located on an outer side of the device region and along a side of the semiconductor substrate where the electrode pads are absent; and
the second concave portion is filled with the light-transmissive adhesive layer.

8. The optical device of claim 6, wherein the electrode pads are provided along two opposing sides of the semiconductor substrate.

9. The optical device of claim 1, further comprising: a through electrode running through the semiconductor substrate and located on an outer side of the device region.

10. The optical device of claim 1, wherein the first concave portion is formed on an outer side of the light-transmissive member.

11. The optical device of claim 9, wherein the first concave portion is formed on an inner side of the light-transmissive member.

12. The optical device of claim 9, further comprising:
a protruding portion provided on a portion of the light-transmissive flattening film that is located on an outer side of a portion where the first concave portion is provided, wherein
the light-transmissive member is placed on the protruding portion.

13. The optical device of claim 1, wherein an inner surface of the first concave portion is tapered.

14. A method for manufacturing an optical device, comprising the steps of:
(a) providing a semiconductor substrate including a device region formed thereon, the device region including at least one of a light-receiving region and a light-emitting region, and forming a light-transmissive flattening film covering the device region on the semiconductor substrate;
(b) forming a concave portion in a region of the light-transmissive flattening film that is located on an outer side of the device region; and
(c) placing a light-transmissive member on the semiconductor substrate and the light-transmissive flattening film so as to cover the device region with a light-transmissive adhesive interposed therebetween, thereby forming a light-transmissive adhesive layer, obtained by curing the light-transmissive adhesive, on the semiconductor substrate and the light-transmissive flattening film filling the concave portion, and bonding the light-transmissive member to the light-transmissive flattening film with the light-transmissive adhesive layer interposed therebetween, after the step (b).

15. The method for manufacturing an optical device of claim 14, wherein
an electrode pad is provided on a same surface as the device region of the semiconductor substrate provided in the step (a); and
the concave portion is provided on an inner side of the electrode pad.

16. The method for manufacturing an optical device of claim 14, further comprising the step of:
(d) forming a protruding portion on a region of the light-transmissive flattening film that is between the concave portion and the electrode pad, after the step (b) and before the step (c), wherein
in the step (c), the light-transmissive member is formed on the light-transmissive adhesive layer and the protruding portion.

17. The method for manufacturing an optical device of claim 16, wherein
a plurality of the electrode pads are provided in a row or rows;
in the step (b), the concave portion is formed so as to extend along the row or rows of the electrode pads; and
in the step (d), the protruding portion is formed so as to extend along the row or rows of the electrode pads.

18. The method for manufacturing an optical device of claim 14, wherein
a planar shape of the semiconductor substrate is rectangular; and
the electrode pads are provided along one or more sides of the semiconductor substrate.

19. The method for manufacturing an optical device of claim 18, wherein in the step (b), a portion of the light-transmissive flattening film that is located along a side of the semiconductor substrate where the electrode pads are absent and that is located on an outer side of the device region is also removed to form the concave portion.

20. The method for manufacturing an optical device of claim 18, wherein the electrode pads are provided along two opposing sides of the semiconductor substrate.

21. The method for manufacturing an optical device of claim 14, wherein the semiconductor substrate provided in the step (a) includes a through electrode running through the semiconductor substrate.

22. The method for manufacturing an optical device of claim 14, wherein the concave portion is provided on an outer side of the light-transmissive member bonded in the step (c).

23. The method for manufacturing an optical device of claim 14, further comprising the step of:
(e) forming a protruding portion on a region of the light-transmissive flattening film that is on an outer side of the concave portion, after the step (b) and before the step (c), wherein
in the step (c), the light-transmissive member is formed on the light-transmissive adhesive layer and the protruding portion.

24. The method for manufacturing an optical device of claim 14, wherein an inner surface of the first concave portion is tapered in the step (b).
